(19) United States
(12) Patent Application Publication
(10) Pub. No.: US 2024/0316944 A1
(43) Pub. Date: Sep. 26, 2024

(54) CHEMICAL LIQUID DISPENSING APPARATUS

(71) Applicant: SEMES CO., LTD., Cheonan-si (KR)

(72) Inventors: Ho Sang LEE, Chungcheongnam-do (KR); Jang Mi WOO, Chungcheongnam-do (KR); Suk Won JANG, Gyeonggi-do (KR)

(73) Assignee: SEMES CO., LTD., Cheonan-si (KR)

(21) Appl. No.: 18/418,676

(22) Filed: Jan. 22, 2024

(30) Foreign Application Priority Data
Mar. 23, 2023 (KR) 10-2023-0037667

(51) Int. Cl. B41J 2/175; B41J 2/18

(52) U.S. Cl. CPC B41J 2/17596; B41J 2/17563; B41J 2/18

(57) ABSTRACT

Provided is a chemical liquid dispensing apparatus including: a head assembly including a channel unit through which a chemical liquid flows, and multiple nozzles through which the chemical liquid flows from the channel unit and dispensing the chemical liquid onto a substrate; and a pipe connected to the head assembly and through which the chemical liquid passes, wherein the channel unit includes a first flow path having a branched structure, and a second flow path connected to the first flow path and supplying the chemical liquid to the multiple nozzles.

### CROSS-REFERENCE TO RELATED APPLICATION

This application claims priority from Korean Patent Application No. 10-2023-0037667 filed on Mar. 23, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a chemical liquid dispensing apparatus.

### 2. Description of the Related Art

A substrate processing method used in processes of displays and semiconductors uses a chemical dispensing apparatus that dispenses a chemical liquid onto a substrate. The chemical liquid for substrate treatment is an ink made of inorganic materials and has high viscosity, and when manufacturing a display device, as a resolution increases, the amount of chemical liquid dispensed from multiple head assemblies needs to be uniform.

Meanwhile, the head assembly may be formed with an inlet and an outlet for a circulation structure. The pressure of the chemical liquid around the inlet of the head assembly is high due to the chemical liquid newly flowing into the head assembly. The pressure of the chemical liquid around the outlet of the head assembly is low due to the chemical liquid discharged from the head assembly. Therefore, a pressure difference may occur between a nozzle adjacent to the inlet of the head assembly and a nozzle adjacent to the outlet thereof, which may reduce the accuracy of impact.

In addition, the chemical liquid is dispensed onto the substrate using multiple head assemblies, and the pressure of the chemical liquid generated in the multiple head assemblies may vary for each head assembly, which may cause a difference in a dispensing speed of the chemical liquid and reduce the accuracy of impact.

### SUMMARY

Aspects of the present disclosure provide a chemical liquid dispensing apparatus in which a pressure difference of a chemical liquid passing through the pipe or head assembly may be reduced and the accuracy of impact may be improved.

Aspects of the present disclosure are not limited to the aspects mentioned above, and other aspects not mentioned will be clearly understood by those skilled in the art from the following description.

According to an aspect of the present disclosure, there is provided a chemical liquid dispensing apparatus including: a head assembly including a channel unit through which a chemical liquid flows, and multiple nozzles through which the chemical liquid flows from the channel unit and dispensing the chemical liquid onto a substrate; and a pipe connected to the head assembly and through which the chemical liquid passes, wherein the channel unit includes a first flow path having a branched structure, and a second flow path connected to the first flow path and supplying the chemical liquid to the multiple nozzles.

According to another aspect of the present disclosure, there is provided a chemical liquid dispensing apparatus including: a storage unit storing a chemical liquid; a head assembly having multiple nozzles for receiving and dispensing the chemical liquid, and provided in plural; and a pipe connecting the plurality of head assemblies and the storage unit and through which the chemical liquid passes, wherein the pipe includes a first line connected to the head assembly and having a branched structure, and a second line connecting the first line and the storage unit.

According to still another aspect of the present disclosure, there is provided a chemical liquid dispensing apparatus including: a head assembly including a channel unit through which a chemical liquid flows and multiple nozzles through which the chemical liquid flows from the channel unit and dispensing the chemical liquid onto a substrate, and provided in plural; a storage unit supplying the chemical liquid to the plurality of head assemblies; and a pipe including a first line connected to the head assembly and having a branched structure formed by a combination of a vertical section and an inclined section, and a second line connecting the first line and the storage unit and having a branched structure formed by a combination of a vertical section and an inclined section, wherein the channel unit includes: a filling channel including a filling port through which the chemical liquid flows and including a filter; and a pumping channel in communication with the filling channel and provided with a first flow path and a second flow path, the first flow path is formed by a combination of a vertical section and an inclined section so that a horizontal section is omitted, and is symmetrical and is branched at the same angle and the same length, and the second flow path is connected to the first flow path, supplies the chemical liquid to the multiple nozzles, is formed by a combination of a vertical section and an inclined section so that a horizontal section is omitted, and is symmetrical and is branched at the same angle and the same length.

The details of other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a chemical liquid dispensing apparatus according to a first exemplary embodiment of the present disclosure;

FIG. 2 is a cross-sectional view illustrating the front of a head assembly of the chemical liquid dispensing apparatus according to the first exemplary embodiment of the present disclosure;

FIG. 3 is a cross-sectional view illustrating a side surface of the head assembly of the chemical liquid dispensing apparatus according to the first exemplary embodiment of the present disclosure;

FIG. 4 is a view illustrating a chemical liquid dispensing apparatus according to a second exemplary embodiment of the present disclosure;

FIG. 5 is a view illustrating a chemical liquid dispensing apparatus according to a third exemplary embodiment of the present disclosure;

FIG. 6 is a view illustrating a chemical liquid dispensing apparatus according to a fourth exemplary embodiment of the present disclosure;

FIG. 7 is a view illustrating a chemical liquid dispensing apparatus according to a fifth exemplary embodiment of the present disclosure;

FIG. 8 is a cross-sectional view illustrating the front of a head assembly of a chemical liquid dispensing apparatus according to a sixth exemplary embodiment of the present disclosure;

FIG. 9 is a perspective view illustrating a branched structure of a second flow path of a chemical liquid dispensing apparatus according to some exemplary embodiments of the present disclosure;

FIG. 10 is a plan view of FIG. 9; and

FIG. 11 is a perspective view illustrating another form of the branched structure of the second flow path of the chemical liquid dispensing apparatus according to some exemplary embodiments of the present disclosure.

### DETAILED DESCRIPTION OF THE EMBODIMENTS

Hereinafter, exemplary embodiments of the present disclosure will be described in detail with reference to the accompanying drawings. Advantages and features of the present disclosure and methods of achieving the same will become apparent with reference to the embodiments described below in detail in conjunction with the accompanying drawings. However, the present disclosure is not limited to exemplary embodiments to be described below, but may be implemented in various different forms, these exemplary embodiments will be provided only in order to make the present disclosure complete and allow those skilled in the art to completely recognize the scope of the present disclosure, and the present disclosure will be defined by the scope of the claims. Throughout the specification, like reference numerals denote like components.

The terms used herein are for the purpose of describing the exemplary embodiments and are not intended to limit the present disclosure. In the present specification, a singular form includes a plural form unless explicitly stated otherwise. Components, steps, operations, and/or elements mentioned by the terms “comprise” and/or “comprising” used in the present disclosure do not exclude the existence or addition of one or more other components, steps, operations, and/or elements.

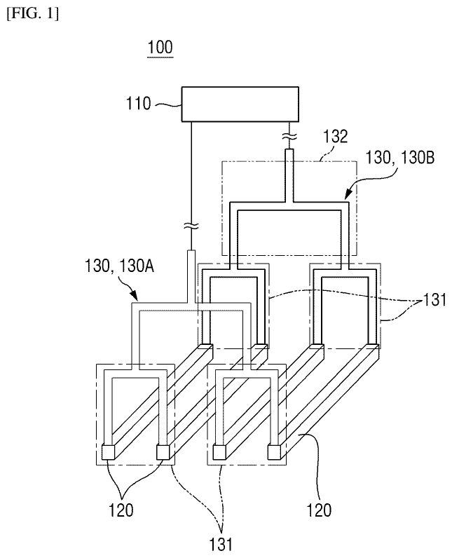

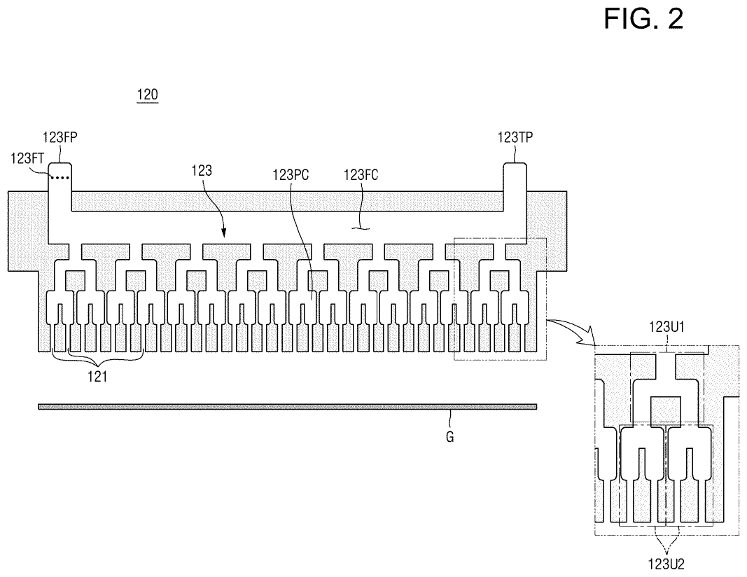

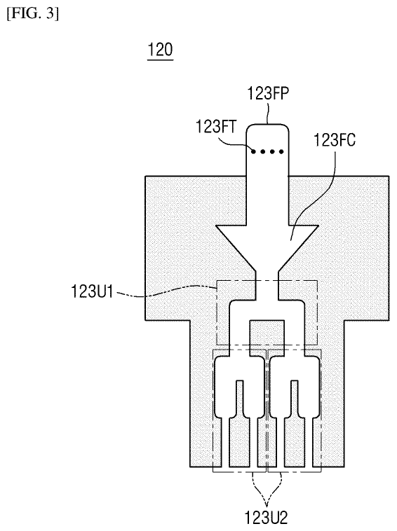

FIG. 1 is a view illustrating a chemical liquid dispensing apparatus according to a first exemplary embodiment of the present disclosure, FIG. 2 is a cross-sectional view illustrating the front of a head assembly of the chemical liquid dispensing apparatus according to the first exemplary embodiment of the present disclosure, and FIG. 3 is a cross-sectional view illustrating a side surface of the head assembly of the chemical liquid dispensing apparatus according to the first exemplary embodiment of the present disclosure.

Referring to FIGS. 1 to 3, a chemical liquid dispensing apparatus according to a first exemplary embodiment of the present disclosure may be provided in an inkjet printing facility and may dispense a chemical liquid to a designated location on a substrate G. The chemical liquid dispensing apparatus 100 may dispense the chemical liquid by changing its relative position with the substrate G. As an example, the substrate G may be fixed and the chemical liquid dispensing apparatus 100 may move, or the chemical liquid dispensing apparatus 100 may be fixed and the substrate G may move.

The chemical liquid dispensing apparatus 100 may include a storage unit 110, a head assembly 120, and a pipe 130.

The storage unit 110 may store a chemical liquid provided as ink and may be positioned above multiple head assemblies 120. The chemical liquid may be supplied from the storage unit 110 to the head assembly 120 by gravity, but is not limited thereto.

Internal pressure of the storage unit 110 may be adjusted to prevent the chemical liquid from being arbitrarily supplied from the storage unit 110 to the head assembly 120. For example, a pressure adjusting device (not illustrated) may be connected to the storage unit 110. The pressure adjusting device may apply negative pressure to the inside of the storage unit 110 so that the chemical liquid inside the storage unit 110 may maintain a meniscus state. Meanwhile, if the negative pressure is not applied to the storage unit 110, the ink may be formed to be convex downward due to gravity and the ink may be dispensed.

There may be a plurality of head assemblies 120. Each head assembly 120 may be provided with multiple nozzles 121 for dispensing the chemical liquid, and the multiple nozzles 121 may be disposed one or more columns.

Referring to FIG. 2, each head assembly 120 may be provided with a channel unit 123 and a filter 123FT together with multiple nozzles 121. The channel unit 123 may include a filling channel 123FC and a pumping channel 123PC.

The chemical liquid supplied from the storage unit 110 may flow into the filling channel 123FC. The filling channel 123FC may be provided with a filling port 123FP through which the chemical liquid flows. Furthermore, the filling channel 123FC may further include a discharge port 123TP so that the chemical liquid dispensing apparatus 100 forms a circulation structure.

The discharge port 123TP may discharge the chemical liquid. In this case, the pipe 130 may be connected to each of the filling port 123FP and the discharge port 123TP. As a result, after the chemical liquid flows into the filling port 123FP, some of the chemical liquid may be discharged onto the substrate G through the nozzle 121, and the remainder may flow back into the storage unit 110 through the discharge port 123TP and be circulated.

The filling channel 123FC may have the filling port 123FP and the discharge port 123TP provided at an upper end thereof. That is, the filling port 123FP and the discharge port 123TP may be positioned at the upper end of the head assembly 120 on the opposite side from the multiple nozzles 121 so that the influence on the pressure and/or speed of the chemical liquid flowing into the multiple nozzles 121 is minimized.

Meanwhile, according to a modified example of the exemplary embodiment, since the discharge port 123TP of the chemical liquid dispensing apparatus 100 is omitted, the chemical liquid may not be circulated.

In addition, the filling channel 123FC may have a structure in which a dead zone where inorganic materials aggregate at a lower portion of a space is reduced. A lower portion of the filling channel 123FC may have a structure that is the same as a diameter of a first flow path 123U1 and whose cross-sectional area increases toward an upper portion. For example, referring to FIG. 3 illustrating the side surface of the head assembly, the filling channel 123FC may have an inverted triangle shape in cross section at the upper portion of the first flow path 123U1.

The pumping channel 123PC may be in communication with the filling channel 123FC. The pumping channel 123PC may form a movement path for the chemical liquid supplied to the multiple nozzles 121. The pumping channel 123PC may have a branched structure to distribute pressure. For example, the pumping channel 123PC may be provided with a first flow path 123U1 and a second flow path 123U2.

At least one of the first flow path 123U1 and the second flow path 123U2 may have a branched structure. It will be described in the present exemplary embodiment that each of the first flow path 123U1 and the second flow path 123U2 forms a branched structure.

The first flow path 123U1 may be in communication with the filling channel 123FC and may have a branched structure to minimize a pressure difference of the chemical liquid. This is to ensure that the chemical liquid flowing through the filling port 123FP does not flow directly into the nozzle 121 adjacent to the filling port 123FP, and also does not flow directly into the nozzle 121 adjacent to the discharge port 123TP. That is, when the first flow path 123U1 has the branched structure, total pressure of the first flow path 123U1 before branching is equal to the sum of all pressures of the branched structure. Therefore, this is because the pressure is distributed in the branched structure compared to the pressure that does not form the branched structure, and the pressure difference between the chemical liquid supplied around the filling port 123FP and the chemical liquid supplied around the discharge port 123TP is also lowered.

The second flow path 123U2 may be in communication with the first flow path 123U1, and may supply the chemical liquid to the multiple nozzles 121. The second flow path 123U2 may have a branched structure identical to or similar to the first flow path 123U1, upstream of the nozzle 121, which is downstream of the first flow path 123U1. According to a modified example of the exemplary embodiment, a diameter of the second flow path 123U2 may be greater than a diameter of the first flow path 123U1, but is not limited thereto.

The filter 123FT may filter the chemical liquid and may cross the filling port 123FP. For example, the filter 123FT may include a porous membrane, but is not limited thereto.

Referring again to FIG. 1, the pipe 130 may connect the storage unit 110 and the head assembly 120, and the chemical liquid may pass through the pipe 130. For example, the pipe 130 may include a supply line 130A to form a movement path through which the chemical liquid passes from the storage unit 110 to the head assembly 120.

In addition, when the head assembly 120 has a circulation structure, the pipe 130 may further include a discharge line 130B. The supply line 130A and the discharge line 130B differ only in the supply and discharge of the chemical liquid and may have the same shape and structure. Therefore, each of the supply line 130A and the discharge line 130B may include a first line 131 and a second line 132.

The pipe 130 may have a branched structure. At least one of the first line 131 and the second line 132 may have a branched structure. Hereinafter, it will be described as an example that both the first line 131 and the second line 132 have a branched structure.

The first line 131 may be connected to the head assembly 120. The first line 131 may have a branched structure to be joined upstream of the plurality of head assemblies 120. The first line 131 may be symmetrical in a parallel arrangement.

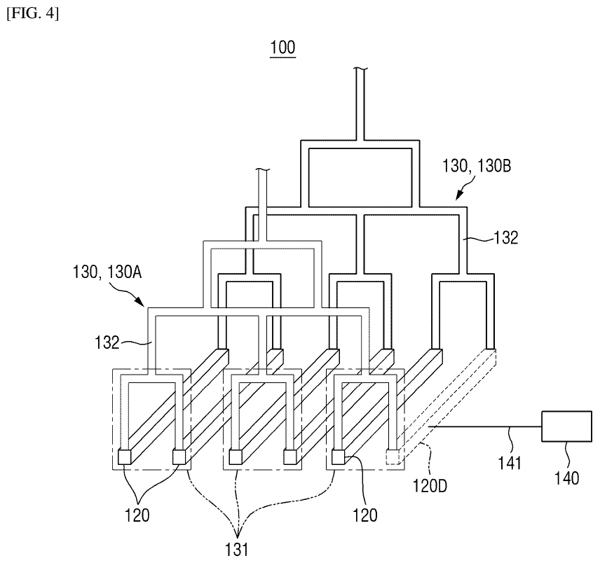

For example, four head assemblies 120 may be provided, and the first line 131 may have two branched structures as two first lines 131 are joined at upstream of the head assemblies 120. As another example, five or more head assemblies 120 may be provided. The provision of five or more head assemblies 120 will be described with reference to FIGS. 4 to 7.

The second line 132 may connect the first line 131 and the storage unit 110 and may have a branched structure. The second line 132 may be symmetrical in a parallel arrangement.

As described above, since the pipe 130 having the branched structure allows pressure to be distributed through the branched structure in the parallel arrangement, a pressure deviation of the chemical liquid supplied to the multiple head assemblies 120 may be reduced.

In addition, since the branched structure of each of the first line 131 and the second line 132 have the same length and angle, the pressure may be uniformly formed by preventing the pressure from being concentrated in one area.

Hereinafter, a modified example of the present exemplary embodiment will be described with reference to FIGS. 4 to 11, and redundant descriptions of the same configuration that perform the same function will be omitted.

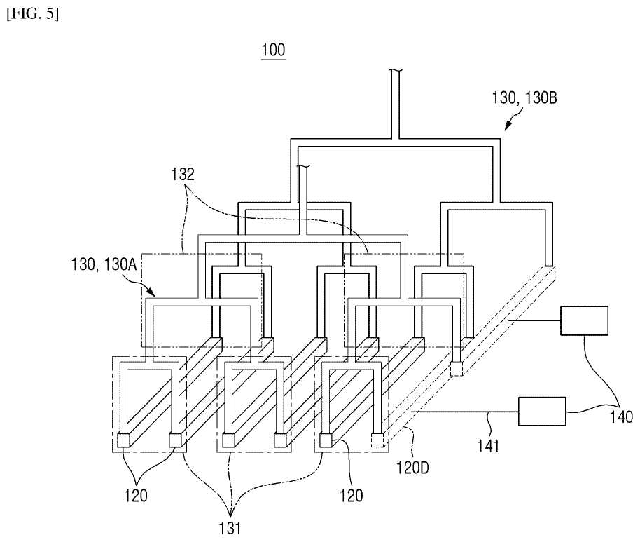

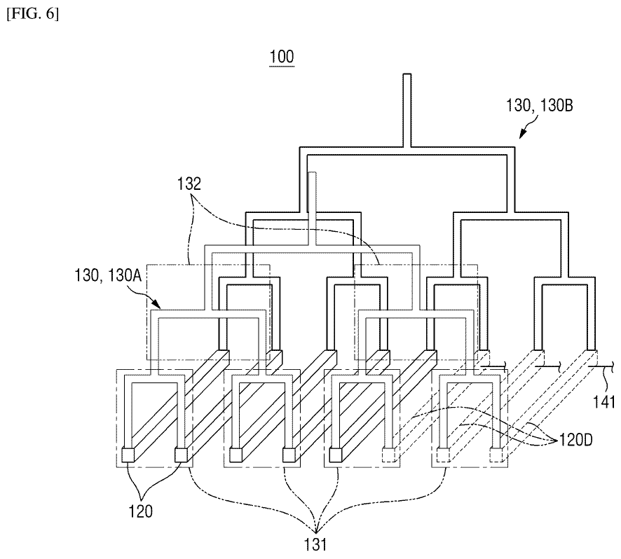

FIG. 4 is a view illustrating a chemical liquid dispensing apparatus according to a second exemplary embodiment of the present disclosure, FIG. 5 is a view illustrating a chemical liquid dispensing apparatus according to a third exemplary embodiment of the present disclosure, and FIG. 6 is a view illustrating a chemical liquid dispensing apparatus according to a fourth exemplary embodiment of the present disclosure.

Differences from those described using FIGS. 1 to 3 will be mainly described with reference to FIGS. 4 to 6.

Referring to FIGS. 4 to 6, in the same or similar manner as the first exemplary embodiment, a chemical liquid dispensing apparatus 100 of the second to fourth exemplary embodiments may include a storage unit 110, a head assembly 120, and a pipe 130.

Meanwhile, the chemical liquid dispensing apparatus 100 of the second to fourth exemplary embodiments may further include an auxiliary unit 120D and an auxiliary storage unit 140, and five head assemblies 120 may be provided. Here, the auxiliary unit 120D may be a dummy head assembly that does not dispense the chemical liquid, or may be a separate auxiliary pipe that supplies the chemical liquid to the auxiliary storage unit 140 rather than to the head assembly 120.

In the pipe 130 of the present exemplary embodiments, a parallel arrangement of the supply line 130A and the discharge line 130B may be symmetrical so that pressure of the chemical liquid flowing in a downstream direction is uniformly formed.

That is, the pressure may be uniformly formed by preventing the pressure from being concentrated on any one area in the branched structure of each of the first line 131 and/or the second line 132 upstream of the head assembly 120.

Here, when five head assemblies 120 are provided, one or more auxiliary units 120D may be provided adjacent to the five head assemblies 120. The auxiliary unit 120D is intended to allow the multiple head assemblies 120 to form a symmetrical structure in an even number. Furthermore, the auxiliary unit 120D is intended to allow the first line 131 and/or the second line 132 to also form a symmetrical structure.

For example, referring to FIGS. 4 and 5, one auxiliary unit 120D may be further added at a position adjacent to the head assembly 120 so that the head assembly 120 has the symmetrical structure.

However, referring to FIG. 5, as the auxiliary unit 120D may also be provided at a lower end of the second line 132 in the symmetrical structure of the first line 131 and/or the second line 132, the auxiliary unit 120D is not limited to being provided adjacent to the head assembly 120.

In addition, referring to FIG. 6, three auxiliary units 120D may be further added so that the first line 131 forms a symmetrical structure in an even form. In other words, various arrangements and numbers of auxiliary units 120D are possible for uniform distribution of the chemical liquid.

In addition, an auxiliary line 141 is provided in the auxiliary unit 120D, so that the chemical liquid of the auxiliary unit 120D may be discharged to the auxiliary storage unit 140 or the storage unit 110 through the auxiliary line 141. In addition, various modified examples are possible. For example, the auxiliary storage unit 140 is connected to the storage unit 110, so that the chemical liquid may be recovered into the storage unit 110, and the auxiliary storage unit 140 is omitted and the auxiliary line 141 is connected to the storage unit 110, so that the chemical liquid may be directly recovered into the storage unit 110.

Hereinafter, other modified examples will be described with reference to the drawings.

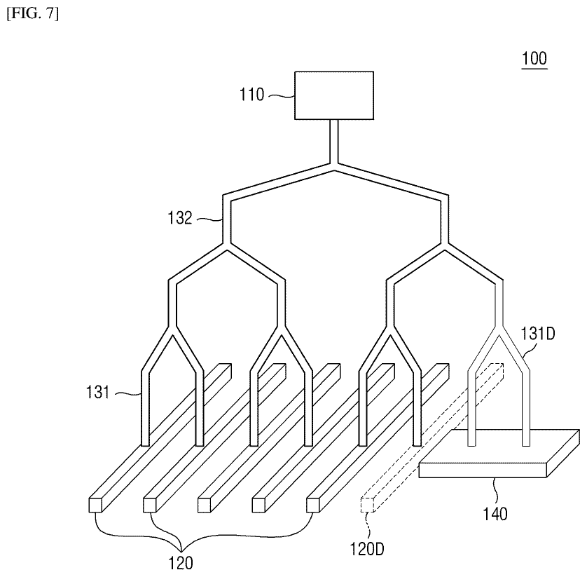

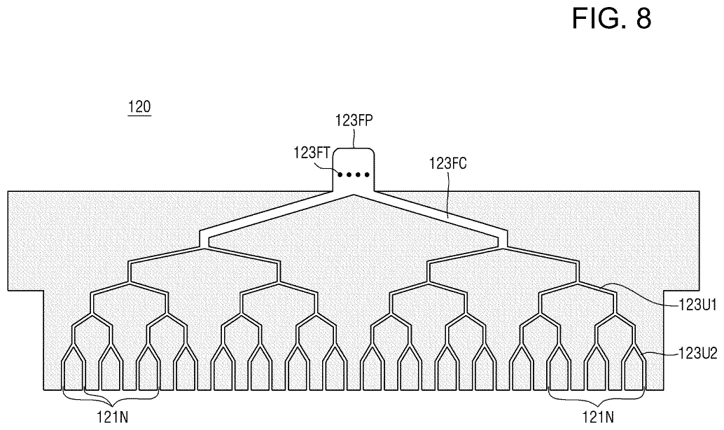

FIG. 7 is a view illustrating a chemical liquid dispensing apparatus according to a fifth exemplary embodiment of the present disclosure, and FIG. 8 is a cross-sectional view illustrating the front of a head assembly of a chemical liquid dispensing apparatus according to a sixth exemplary embodiment of the present disclosure. Differences from those described using FIGS. 1 to 6 will be mainly described with reference to FIGS. 7 and 8.

Referring to FIGS. 7 and 8, in the same or similar manner as the first to fifth exemplary embodiments, a chemical liquid dispensing apparatus 100 of the fifth and sixth exemplary embodiments may include a storage unit 110, a head assembly 120, and a pipe 130.

Meanwhile, in the chemical liquid dispensing apparatus 100 of the fifth and sixth exemplary embodiments, any one of multiple outlets of the first line 131 is not connected to the head assembly 120 and may be connected not only to the auxiliary unit 120D provided as the dummy head assembly but also to the auxiliary storage unit 140. Alternatively, all outlets that are not connected to the head assembly 120 among the multiple outlets of the first line 131 may also be connected to the auxiliary storage unit 140. In other words, outlets that are not connected to the head assembly 120 and are opened among the multiple outlets of the first line 131 may be connected to the auxiliary unit 120D or the auxiliary storage unit 140.

In addition, in the chemical liquid dispensing apparatus 100 of the fifth and sixth exemplary embodiments, a horizontal section may be omitted in the branched structure of the head assembly 120, or a horizontal section may be omitted in the branched structure of the pipe 130.

In addition, the chemical liquid may not be circulated in the chemical liquid dispensing apparatus 100. Accordingly, in the chemical liquid dispensing apparatus 100 of the present exemplary embodiment, the discharge port 123TP and the discharge line 130B may be omitted. In addition, the discharge port 123TP may be omitted, and the filling port 123FP may be provided at the center of the upper end of the filling channel 123FC.

In addition, the branched structure of the pipe 130 and/or the branched structure of the head assembly 120 may be formed by a combination of a vertical section and an inclined section to omit a horizontal section to prevent agglomeration of inorganic materials.

For example, referring to FIG. 7, each of the first line 131 and the second line 132 may be formed by a combination of a vertical section and an inclined section so that a horizontal section is omitted, and may have a reverse ‘Y’ shape.

In addition, referring to FIG. 8, each of the first flow path 123U1 and the second flow path 123U2 of the head assembly 120 may be formed by a combination of a vertical section and an inclined section so that a horizontal section is omitted, and may have a reverse ‘Y’ shape.

Meanwhile, the first flow path 123U1 and the second flow path 123U2 are not limited to a two-branched structure, and various modified examples are possible.

Furthermore, various modified examples of the filling channel 123FC are possible. For example, referring to FIG. 8, the filling channel 123FC may have a branched structure with an inclined section downstream of the filling port 123FP.

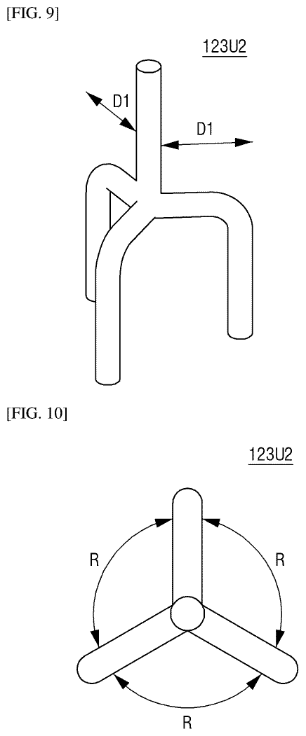

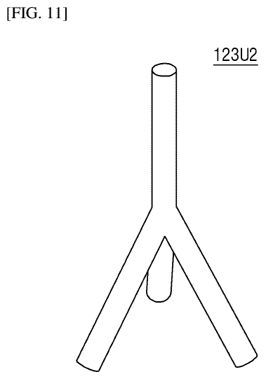

FIG. 9 is a perspective view illustrating a branched structure of a second flow path of a chemical liquid dispensing apparatus according to some exemplary embodiments of the present disclosure, and FIG. 10 is a plan view of FIG. 9. In addition, FIG. 11 is a perspective view illustrating another form of the branched structure of the second flow path of the chemical liquid dispensing apparatus according to some exemplary embodiments of the present disclosure.

Referring to FIGS. 9 to 11, the second flow path 123U2 may have a three-branched structure. Therefore, although not illustrated in the drawing, the second flow path 123U2 may also have a four- or five-branched structure.

In the branched structure of the pipe 130 and the branched structure of the head assembly 120 of the present exemplary embodiments, the branched structures may be symmetrical and branched at the same angle and the same length so that the pressure is uniformly formed.

For example, since the branched structures of each of the first flow path 123U1 and the second flow path 123U2 may be symmetrical and branched at the same angle and the same length, branched lengths of the second flow paths 123U2 (see the identification number ‘D1’ in FIG. 9) may be all the same, and angles at which the second flow paths 123U2 are branched (see the identification number ‘R’ in FIG. 10) may be all the same.

In addition, since the branching at the same angle and the same length is not limited to the first flow path 123U1 and the second flow path 123U2, the first line 131 and the second line 132 may also be branched at the same angle and the same length. In addition, when the first flow path 123U1, the second flow path 123U2, the first line 131, and the second line 132 are branched into three or more branches, the first flow path 123U1, the second flow path 123U2, the first line 131, and the second line 132 may be branched into three or more branches at one outlet so that fluid pressure is formed at uniform pressure as illustrated in FIGS. 9 and 11.

In addition, in the branched structure of the present exemplary embodiments, as illustrated in FIG. 4, the three branched structures of the first line 131 may be connected to the three-branched structure of the second line 132, but preferably, the second line 132 has the branched structure and may be connected to the first line 131 by forming a unit at every two branches. For example, as illustrated in FIGS. 1, 5, and 6, each of the two branched structures of the first line 131 may be connected to the second line 132 having two branches.

That is, the first lines 131 provided in a row are connected to the second line branched into two branches upstream of the first line 131 for each pair of first lines 131, and may not be connected to the second line 132 or the three-branched second line 132 to which another pair of first lines 131 or another first line 131 is connected.

This is because when the chemical liquid passes from the three-branched second line 132 to the three first lines 131 as illustrated in FIG. 4, the chemical liquid flows into one first line 131 in the middle unlike the first lines 131 on both sides from both sides of the two branches upstream of the three branches of the second line 132, and the fluid pressure may be different from that of the neighboring first line 131. As described above, the branched structure of the present exemplary embodiment may form a structure in which each of the two branched structures of the first line 131 is connected to the second line 132 having two branches so that so that uniform fluid pressure is formed from the second line 132 to the first line 131 in the downstream flow of the pipe 130. In addition, the upstream of the second line 132 may also be connected to form a unit of two branches.

The chemical liquid dispensing apparatus 100 according to the exemplary embodiments of the present disclosure as described above may reduce the pressure deviation of the chemical liquid and reduce the speed deviation caused by the pressure deviation, thereby improving the impact accuracy. In other words, by reducing the pressure deviation between the multiple nozzles 121 provided in the head assembly 120, the speed deviation of the chemical liquid discharged from the multiple nozzles 121 may be reduced.

In addition, by reducing the pressure deviation between the first line 131 (or second line 132) of the pipe 130 that supplies the chemical liquid to the multiple head assemblies 120, the speed deviation caused by the pressure deviation may be reduced, thereby improving the impact accuracy

Meanwhile, another exemplary embodiment is possible by combining any one or more of the first to sixth exemplary embodiments and known technologies. For example, the omitting of the horizontal section in the branched structure of the head assembly 120 or the omitting of the horizontal section in the branched structure of the pipe 130 of the fifth and sixth exemplary embodiments is combined with the first to fourth embodiments, so that the horizontal section may be omitted in the branched structure while the chemical liquid dispensing apparatus 100 forms a circulation structure.

Although the exemplary embodiments of the present disclosure have been described with reference to the accompanying drawings, those of ordinary skill in the art to which the present disclosure pertains will understand that the present disclosure may be embodied in other specific forms without changing the technical spirit or essential features thereof. Therefore, it should be understood that the exemplary embodiments described above are illustrative in all aspects and not restrictive.

What is claimed is:

1. A chemical liquid dispensing apparatus comprising:
a head assembly including a channel unit through which a chemical liquid flows, and multiple nozzles through which the chemical liquid flows from the channel unit and dispensing the chemical liquid onto a substrate; and
a pipe connected to the head assembly and through which the chemical liquid passes,
wherein the channel unit includes a first flow path having a branched structure, and a second flow path connected to the first flow path and supplying the chemical liquid to the multiple nozzles.

2. The chemical liquid dispensing apparatus of claim 1, wherein the second flow path has a branched structure.

3. The chemical liquid dispensing apparatus of claim 2, wherein at least one of the first flow path and the second flow path is formed by a combination of a vertical section and an inclined section so that a horizontal section is omitted.

4. The chemical liquid dispensing apparatus of claim 2, wherein the first flow path has a symmetrical branched structure and is branched at the same angle and the same length, and
the second flow path is has a symmetrical branched structure and is branched at the same angle and the same length.

5. The chemical liquid dispensing apparatus of claim 1, wherein the channel unit includes:
a filling channel provided with a filling port through which the chemical liquid flows; and
a pumping channel in communication with the filling channel and provided with the first flow path and the second flow path.

6. The chemical liquid dispensing apparatus of claim 5, wherein the filling channel is branched from the filling port with an inclined section.

7. The chemical liquid dispensing apparatus of claim 5, wherein the filling channel has a lower portion equal to a diameter of the first flow path and a cross-sectional area that increases toward an upper portion, in terms of a longitudinal direction.

8. The chemical liquid dispensing apparatus of claim 5, wherein the head assembly further includes a filter that crosses the filling port and filters the chemical liquid.

9. The chemical liquid dispensing apparatus of claim 5, wherein the filling channel further includes a discharge port through which the chemical liquid is discharged so that the chemical liquid circulates, and
the pipe is connected to each of the filling port and the discharge port.

10. The chemical liquid dispensing apparatus of claim 1, wherein the head assembly is provided in plural and further includes a storage portion that supplies the chemical liquid to the plurality of head assemblies,
the pipe includes a first line connected to the head assembly and a second line connecting the first line and the storage unit, and
the first line is joined upstream of the plurality of head assemblies and has a branched structure.

11. The chemical liquid dispensing apparatus of claim 10, wherein five head assemblies are provided,
the chemical liquid dispensing apparatus further includes a dummy head assembly adjacent to the head assembly and not dispensing the chemical liquid or an auxiliary storage unit in which the chemical liquid is stored, and
any one of multiple outlets of the first line is connected to the dummy head assembly or the auxiliary storage unit.

12. The chemical liquid dispensing apparatus of claim 10, wherein the second line has a branched structure and is connected to the first line by forming a unit at every two branches.

13. The chemical liquid dispensing apparatus of claim 12, wherein at least one of the first line and the second line is formed by a combination of a vertical section and an inclined section so that a horizontal section is omitted.

14. A chemical liquid dispensing apparatus comprising:
a storage unit storing a chemical liquid;
a head assembly having multiple nozzles for receiving and dispensing the chemical liquid, and provided in plural; and
a pipe connecting the plurality of head assemblies and the storage unit and through which the chemical liquid passes,
wherein the pipe includes a first line connected to the head assembly and having a branched structure, and a second line connecting the first line and the storage unit.

15. The chemical liquid dispensing apparatus of claim 14, wherein the head assembly includes a filling port through which the chemical liquid flows.

16. The chemical liquid dispensing apparatus of claim 15, wherein the head assembly further includes a discharge port through which the chemical liquid is discharged so that the chemical liquid circulates, and
the pipe is connected to each of the filling port and the discharge port.

17. The chemical liquid dispensing apparatus of claim 14, wherein the second line has a branched structure.

18. The chemical liquid dispensing apparatus of claim 17, wherein the first line has a symmetrical branched structure and is branched at the same angle and the same length, and
the second line has a symmetrical branched structure and is branched at the same angle and the same length, and is connected to the first line by forming a unit at every two branches.

19. A chemical liquid dispensing apparatus comprising:
a head assembly including a channel unit through which a chemical liquid flows and multiple nozzles through which the chemical liquid flows from the channel unit and dispensing the chemical liquid onto a substrate, and provided in plural;
a storage unit supplying the chemical liquid to the plurality of head assemblies; and
a pipe including a first line connected to the head assembly and having a branched structure formed by a combination of a vertical section and an inclined section, and a second line connecting the first line and the storage unit and having a branched structure formed by a combination of a vertical section and an inclined section,
wherein the channel unit includes:
a filling channel including a filling port through which the chemical liquid flows and including a filter; and
a pumping channel in communication with the filling channel and provided with a first flow path and a second flow path,
the first flow path is formed by a combination of a vertical section and an inclined section so that a horizontal section is omitted, and is symmetrical and is branched at the same angle and the same length, and
the second flow path is connected to the first flow path, supplies the chemical liquid to the multiple nozzles, is formed by a combination of a vertical section and an inclined section so that a horizontal section is omitted, and is symmetrical and is branched at the same angle and the same length.
